(19) United States
(12) Patent Application Publication
(10) Pub. No.: US 2026/0205057 A1
(43) Pub. Date: Jul. 16, 2026

(54) VOLTAGE COMBINED DIFFERENTIAL DOHERTY COMBINER

(71) Applicant: QUALCOMM Incorporated, San Diego, CA (US)

(72) Inventors: Muslum Emir AVCI, Marlborough, MA (US); Jing-Hwa CHEN, Sudbury, MA (US); Junzhi YU, Marlborough, MA (US); Xinwei WANG, Dunstable, MA (US); Xiangdong ZHANG, Westford, MA (US)

(21) Appl. No.: 19/017,051

(22) Filed: Jan. 10, 2025

(51) Int. Cl. H03F 1/02; H03F 1/56; H03F 3/24

(52) U.S. Cl. CPC H03F 1/0288; H03F 1/565; H03F 3/245; H03F 2200/451; H03F 2200/541

(57) ABSTRACT

A power amplifier includes a main amplifier and an auxiliary amplifier. The power amplifier also includes a first transformer including a first inductor coupled between a first output of the main amplifier and a second output of the main amplifier, and a second inductor magnetically coupled with the first inductor. The power amplifier also includes a second transformer including a third inductor coupled between a first output of the auxiliary amplifier and a second output of the auxiliary amplifier, and a fourth inductor magnetically coupled with the third inductor, wherein the second inductor and the fourth inductor are coupled in series. The power amplifier further includes a first capacitor coupled in parallel with the third inductor, and a second capacitor coupled in parallel with the fourth inductor, wherein the third inductor, the fourth inductor, the first capacitor, and the second capacitor are configured to provide impedance inversion.

### BACKGROUND

### Field

Aspects of the present disclosure relate generally to wireless communications, and, more particularly, to power amplifiers.

### Background

A wireless device includes a transmitter for transmitting radio frequency (RF) signals via one or more antennas. The transmitter may include power amplifiers for amplifying the RF signals before transmission. A power amplifier may be implemented with a Doherty amplifier, which includes a main amplifier and an auxiliary amplifier.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a power amplifier. The power amplifier includes a main amplifier and an auxiliary amplifier. The power amplifier also includes a first transformer including a first inductor coupled between a first output of the main amplifier and a second output of the main amplifier, and a second inductor magnetically coupled with the first inductor. The power amplifier also includes a second transformer including a third inductor coupled between a first output of the auxiliary amplifier and a second output of the auxiliary amplifier, and a fourth inductor magnetically coupled with the third inductor, wherein the second inductor and the fourth inductor are coupled in series. The power amplifier further includes a first capacitor coupled in parallel with the third inductor, and a second capacitor coupled in parallel with the fourth inductor, wherein the third inductor, the fourth inductor, the first capacitor, and the second capacitor are configured to provide impedance inversion.

A second aspect relates to a system. The system includes a mixer and an input network, wherein an input of the input network is coupled to the mixer. The system also includes a main amplifier, wherein an input of the main amplifier is coupled to a first output of the input network, and an auxiliary amplifier, wherein an input of the auxiliary amplifier is coupled to a second output of the input network. The system also includes a first transformer including a first inductor coupled between a first output of the main amplifier and a second output of the main amplifier, and a second inductor magnetically coupled with the first inductor. The system also includes a second transformer including a third inductor coupled between a first output of the auxiliary amplifier and a second output of the auxiliary amplifier, and a fourth inductor magnetically coupled with the third inductor, wherein the second inductor and the fourth inductor are coupled in series. The system also includes a first capacitor coupled in parallel with the third inductor, and a second capacitor coupled in parallel with the fourth inductor, wherein the third inductor, the fourth inductor, the first capacitor, and the second capacitor are configured to provide impedance inversion.

A third aspect relates to a power amplifier. The power amplifier includes a main amplifier and an auxiliary amplifier. The power amplifier also includes a first transformer including a first inductor coupled between a first output of the main amplifier and a second output of the main amplifier, and a second inductor magnetically coupled with the first inductor. The power amplifier also includes a second transformer including a third inductor coupled between a first output of the auxiliary amplifier and a second output of the auxiliary amplifier, wherein the first inductor and the third inductor are stacked, and a fourth inductor magnetically coupled with the third inductor, wherein the second inductor and the fourth inductor are coupled in series. The power amplifier also includes a first cross capacitor coupled between the first output of the main amplifier and the first output of the auxiliary amplifier, and a second cross capacitor coupled between the second output of the main amplifier and the second output of the auxiliary amplifier.

### BRIEF DESCRIPTION OF THE DRAWINGS

FIG. 1 shows an example of a Doherty amplifier including a main amplifier, an auxiliary amplifier, and a voltage combiner according to certain aspects of the present disclosure.

FIG. 2 shows an example of a voltage combiner including a first transformer and a second transformer in which the first transformer includes a first inductor and a second inductor and the second transformer includes a third inductor and a fourth inductor according to certain aspects of the present disclosure.

FIG. 3 shows an example in which a capacitor of FIG. 2 is split into an on-die capacitor and an off-die capacitor according to certain aspects of the present disclosure.

FIG. 4 shows a top view of an exemplary layout of the first inductor according to certain aspects of the present disclosure.

FIG. 5 shows a top view of an exemplary layout of the second inductor and the fourth inductor according to certain aspects of the present disclosure.

FIG. 6 shows a top view of an exemplary layout of the third inductor according to certain aspects of the present disclosure.

FIG. 7 shows a top view of an example in which the inductors of FIGS. 4, 5, and 6 are stacked according to certain aspects of the present disclosure.

FIG. 8 shows an example of cross capacitors coupled between the outputs of the main amplifier and the auxiliary amplifier according to certain aspects of the present disclosure.

FIG. 9A shows an example of a mixer coupled to the Doherty amplifier according to certain aspects of the present disclosure.

FIG. 9B shows an example of a driver amplifier coupled between the mixer and the Doherty amplifier of FIG. 9A according to certain aspects of the present disclosure.

FIG. 10 is a diagram of an environment including a wireless device that includes a transceiver according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

Doherty amplifiers are widely used in transmitters to amplify RF signals before transmission. For example, a Doherty amplifier (also referred to as a Doherty power amplifier (PA)) may be used in a wireless device to provide efficient power amplification for a RF signal having a high peak-to-average power ratio (PAPR).

A Doherty amplifier includes a main amplifier and an auxiliary amplifier. The main amplifier may be biased in class AB and the auxiliary amplifier may be biased in class C. The main amplifier may also be referred to as the carrier amplifier and the auxiliary amplifier may also be referred to as the peaking amplifier.

During operation, a power splitter splits the input RF signal into a first RF signal and a second RF signal in which the first RF signal is input to the main amplifier and the second RF signal is input to the auxiliary amplifier. In addition, a phase shifter may shift the phase of the first input RF signal (e.g., by 90 degrees) before input to the main amplifier or shift the phase of the second input RF signal (e.g., by 90 degrees) before input to the auxiliary amplifier.

The output RF signal of the main amplifier and the output RF signal of the auxiliary amplifier are combined into a combined output RF signal by a combiner (also referred to as an output network) and output to an antenna for transmission. The combiner may be implemented with a current combiner or a voltage combiner. A voltage combiner can achieve a broader bandwidth than a current combiner and is therefore more suitable to cover a wide bandwidth and/or cover multiple cellular bands.

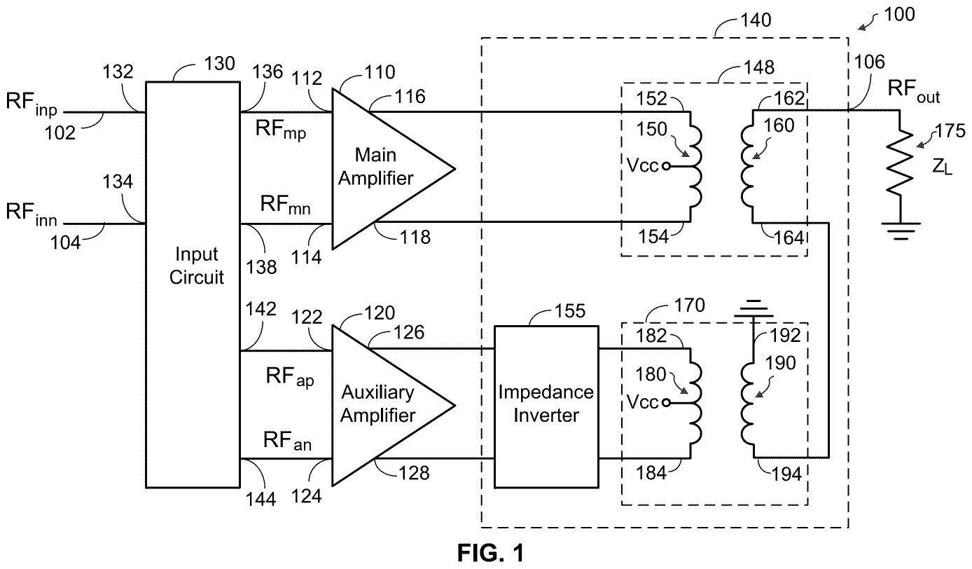

FIG. 1 shows an example of a Doherty amplifier 100 with voltage combining (also referred to as voltage-mode combining) according to certain aspects. The Doherty amplifier 100 may be included in a wireless device (e.g., a mobile device or a base station) for amplifying an RF signal before transmission via one or more antennas. In the example in FIG. 1, the Doherty amplifier 100 includes an input circuit 130 (also referred to as an input network), a main amplifier 110, an auxiliary amplifier 120, and a voltage combiner 140 (also referred to as an output network). As discussed further below, the voltage combiner 140 is configured to combine the output RF signal of the main amplifier 110 and the output RF signal of the auxiliary amplifier 120 into a combined RF signal using voltage combining, and output the combined RF signal at the output of the voltage combiner. The output of the voltage combiner 140 is coupled to a load 175 having an impedance of Z_{L} (e.g., 50 Ohms). The load 175 may be the load of an antenna, a transmission line, or the like.

In the example in FIG. 1, the Doherty amplifier 100 has a differential input including a first input 102 and a second input 104. The differential input is configured to receive a differential input RF signal including a first input RF signal RFᵢₙₚ received at the first input 102 and a second input RF signal RFᵢₙₙ received at the second input 104. The differential input RF signal may be generated by a mixer (not shown in FIG. 1) configured to frequency upconvert a baseband signal or an intermediate frequency (IF) signal into the differential input RF signal. The Doherty amplifier 100 also has an output 106 coupled to the load 175 (e.g., an antenna). The Doherty amplifier 100 is configured to amplify the differential input RF signal, and output the resulting amplified RF signal RFₒᵤₜ (i.e., the combined RF signal discussed above) at the output 106 for transmission via an antenna.

The input circuit 130 (also referred to as an input network) has a differential input including a first input 132 and a second input 134. The first input 132 is coupled to the first input 102 of the Doherty amplifier 100 and the second input 134 is coupled to the second input 104 of the Doherty amplifier 100. The input circuit 130 is configured to receive the differential input RF signal at the first and second inputs 132 and 134 and split the differential input RF signal into a first differential RF signal and a second differential RF signal. The input circuit 130 may also provide a phase shift (e.g., 90 degrees) between the first differential RF signal and the second differential RF signal to provide phase compensation, as discussed further below. For example, the input circuit 130 may provide the phase shift by phase shifting the first differential RF signal relative to the second differential RF or phase shifting the second differential RF signal relative to the first differential RF signal. The input circuit 130 may include one or more quarter-wavelength transmission lines and/or one or more lumped inductor-capacitor (LC) networks to perform the phase shift. However, it is to be appreciated that the input circuit 130 is not limited to these examples. The input circuit 130 may also include impedance matching networks for providing input impedance matching.

The input circuit 130 has a first differential output including a first output 136 and a second output 138 for outputting the first differential RF signal. The first differential RF signal includes RF signals RFₘₚ and RFₘₙ that are output from the first output 136 and the second output 138, respectively, of the input circuit 130.

The input circuit 130 also has a second differential output including a third output 142 and a fourth output 144 for outputting the second differential RF signal. The second differential RF signal includes RF signals RFₐₚ and RFₐₙ that are output from the third output 142 and the fourth output 144, respectively, of the input circuit 130.

The main amplifier 110 has a differential input including a first input 112 and a second input 114 and a differential output including a first output 116 and a second output 118. The first input 112 is coupled to the first output 136 of the input circuit 130 and the second input 114 is coupled to the second output 138 of the input circuit 130 to receive the first differential RF signal from the input circuit 130. The main amplifier 110 may be biased in class AB and may be on (i.e., active) when the main amplifier 110 is provided with a supply voltage. The main amplifier 110 is configured to amplify the first differential RF signal and output the resulting amplified differential RF signal at the differential output of the main amplifier 110. The main amplifier 110 may include one or more amplifier stages.

The auxiliary amplifier 120 has a differential input including a first input 122 and a second input 124 and a differential output including a first output 126 and a second output 128. The first input 122 is coupled to the third output 142 of the input circuit 130 and the second input 124 is coupled to the fourth output 144 of the input circuit 130 to receive the second differential RF signal from the input circuit 130. The auxiliary amplifier 120 may be biased in class C. The auxiliary amplifier 120 is configured to amplify the second differential RF signal and output the resulting amplified differential RF signal at the differential output of the auxiliary amplifier 120. The auxiliary amplifier 120 may include one or more amplifier stages.

In the example in FIG. 1, the voltage combiner 140 includes a first transformer 148, an impedance inverter 155, and a second transformer 170. The first transformer 148 includes a first inductor 150 and a second inductor 160 magnetically coupled with the first inductor 150. The first inductor 150 may also be referred to as the primary inductor of the first transformer 148 and the second inductor 160 may also be referred to as the secondary inductor of the first transformer 148. In this example, the first inductor 150 is coupled between the outputs 116 and 118 of the main amplifier 110. More particularly, a first terminal 152 of the first inductor 150 is coupled to the first output 116 of the main amplifier 110 and a second terminal 154 of the first inductor 150 is coupled to the second output 118 of the main amplifier 110. The center tap of the first inductor 150 may be DC biased by supply voltage Vcc, as shown in FIG. 1. The second inductor 160 has a first terminal 162 coupled to the load 175 (e.g., antenna) and a second terminal 164.

The second transformer 170 includes a third inductor 180 and a fourth inductor 190 magnetically coupled with the third inductor 180. The third inductor 180 may also be referred to as the primary inductor of the second transformer 170 and the fourth inductor 190 may also be referred to as the secondary inductor of the second transformer 170. The center tap of the third inductor 180 may be DC biased by the supply voltage Vcc, as shown in FIG. 1. The fourth inductor 190 has a first terminal 192 coupled to ground (or some reference potential) and a second terminal 194 coupled to the second terminal 164 of the second inductor 160.

The impedance inverter 155 is coupled between the first output 126 of the auxiliary amplifier 120 and a first terminal 182 of the third inductor 180 and between the second output 128 of the auxiliary amplifier 120 and a second terminal 184 of the third inductor 180. The impedance inverter 155 is discussed further below.

In the example in FIG. 1, the second inductor 160 and the fourth inductor 190 are coupled in series between the load 175 and ground (or some reference potential) to combine the voltages of the RF output signals of the main amplifier 110 and the auxiliary amplifier 120. Thus, in this example, the voltage combining is provided by coupling the second inductor 160 and the fourth inductor 190 in series.

During operation, the impedance inverter 155 provides load modulation that allows the Doherty amplifier 100 to achieve high power efficiency when the main amplifier 110 is driven in the saturation region. The impedance inverter 155 also introduces a phase shift (e.g., 90-degree phase shift). The phase shift in the input circuit 130 discussed above compensates for the phase shift of the impedance inverter 155 in order to provide in-phase power combining at the output 106 of the Doherty amplifier 100.

The impedance inverter 155 may be implemented with quarter-wavelength transmission lines, a transformer, and/or a lumped LC network. A challenge with the impedance inverter 155 is that the impedance inverter 155 takes up a large area, which increases the size of the transmitter.

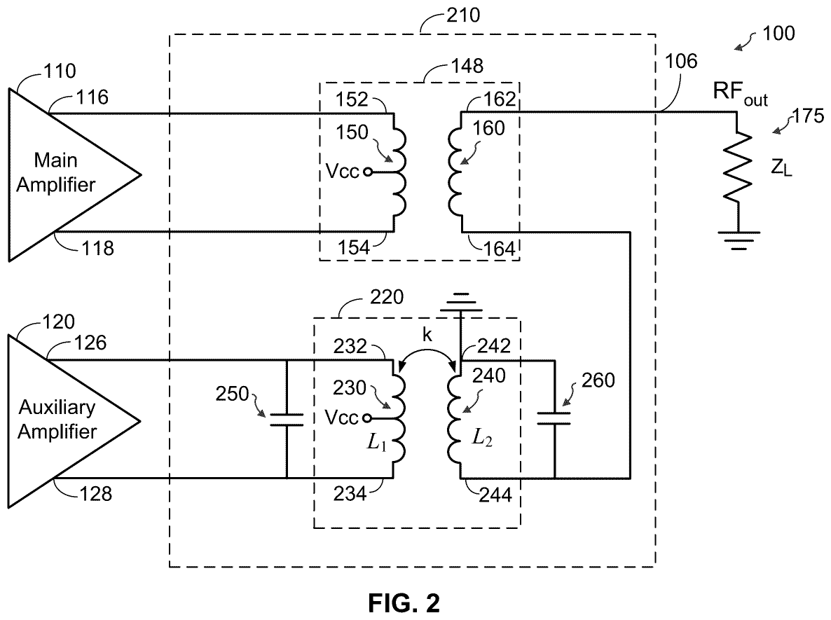

FIG. 2 shows an exemplary voltage combiner 210 for the Doherty amplifier 100 that provides area reduction according to certain aspects of the present disclosure. In this example, the voltage combiner 210 includes the first transformer 148 discussed above with reference to FIG. 1. The voltage combiner 210 also includes a second transformer 220 in which the second transformer 220 is configured to perform impedance inversion in addition to voltage combining with the first transformer 148, as discussed further below. This eliminates the need for the separate impedance inverter 155 shown in FIG. 1, which helps reduce the area of the voltage combiner 210. Note that the input circuit 130 is not shown in FIG. 2 for ease of illustration.

In this example, the second transformer 220 includes a third inductor 230 and a fourth inductor 240 magnetically coupled with the third inductor 230 with a coupling factor k. The third inductor 230 may also be referred to as the primary inductor of the second transformer 220 and the fourth inductor 240 may also be referred to as the secondary inductor of the second transformer 220. The third inductor 230 is coupled between the outputs 126 and 128 of the auxiliary amplifier 120 (i.e., peaking amplifier). More particularly, a first terminal 232 of the third inductor 230 is coupled to the first output 126 of the auxiliary amplifier 120 and a second terminal 234 of the third inductor 230 is coupled to the second output 128 of the auxiliary amplifier 120. The center tap of the third inductor 230 may be DC biased by the supply voltage Vcc.

The fourth inductor 240 has a first terminal 242 coupled to ground (or some reference potential) and a second terminal 244 coupled to the second terminal 164 of the second inductor 160. As a result, the fourth inductor 240 and the second inductor 160 are coupled in series between the load 175 and ground (or some reference potential), which provides the voltage combining discussed above.

In this example, the voltage combiner 210 also includes a first capacitor 250 coupled in parallel with the third inductor 230 and a second capacitor 260 coupled in parallel with the fourth inductor 240. Each of the capacitors 250 and 260 may include a metal-oxide-metal (MOM) capacitor, a metal-insulator-metal (MIM) capacitor, a metal-oxide-semiconductor (MOS) capacitor, or any combination thereof. Each of the capacitors 250 and 260 may be integrated on a chip (i.e., die), implemented with metal plates on and/or embedded in a printed circuit board (PCB) or a multi-layer laminate, or the like.

In certain aspects, the capacitors 250 and 260 and the inductors 230 and 240 of the second transformer 220 are configured to provide impedance inversion. For example, the capacitors 250 and 260 and the inductors 230 and 240 may be configured to provide impedance inversion and impedance scaling based on the following equation:

$${Z}_{inv} = \frac{{Z}_{0}^{2}}{{Z}_{L}} \qquad ( 1 )$$

where Zᵢₙᵥ is the impedance seen at the auxiliary amplifier 120, Z_{L} is the load impedance, and Z₀ is an impedance scaling factor. In this example, the load impedance Z_{L} in the denominator represents the impedance inversion.

The impedance scaling factor Z₀ may be set to a value that achieves a desired impedance at the auxiliary amplifier 120 at the same time as impedance inversion. For instance, in one example, an impedance of 10 Ohms at the auxiliary amplifier 120 may be desired to achieve high power efficiency at the back-off power (e.g., 6 dB below peak power) of the Doherty amplifier 100. In this example, the load impedance may be 50 Ohm. In this example, to achieve the desired impedance of 10 Ohm at the auxiliary amplifier 120, the scaling factor Z₀ may be set as follows:

$${Z}_{0} = \sqrt{{Z}_{L} \times {Z}_{inv}} = \sqrt{50 \times 10} = \sqrt{500} . \qquad ( 2 )$$

Plugging in the scaling factor in equation (2) into the equation (1) results in an impedance Zᵢₙᵥ of 10 Ohm at the auxiliary amplifier 120. It is to be appreciated that the present disclosure is not limited to this example and that the scaling factor Z₀ may be set to other values depending on the desired impedance (i.e., Zᵢₙᵥ) at the auxiliary amplifier 120 and the load impedance. The desired impedance may be determined, for example, by plotting the power efficiency of the Doherty amplifier 100 (e.g., at the back-off power) as a function of the impedance (i.e., Zᵢₙᵥ) at the auxiliary amplifier 120 and choosing an impedance that provides high power efficiency. However, it is to be appreciated that the present disclosure is not limited to this example.

Once the scaling factor Z₀ for achieving the desired impedance at the auxiliary amplifier 120 is known, the inductance values for the inductors 230 and 240 of the second transformer 220 may be set based on the following:

$${L}_{1} = {L}_{2} = {Z}_{0} \frac{k}{1 - {k}^{2}} \frac{1}{j ω} \qquad ( 3 )$$

where k is the coupling factor between the inductors 230 and 240, Co is an angular frequency of the input RF signal, and L₁ and L₂ are the inductances of the primary inductor and the secondary inductor of the second transformer 220 (i.e., the third inductor 230 and the fourth inductor 240). The capacitance values for the capacitors 250 and 260 may be set based on the following:

$${C}_{t} = \frac{1}{{L}_{1} ( 1 - {k}^{2} ) {ω}^{2}} \qquad ( 4 )$$

where Cₜ is the capacitance of each of the capacitors 250 and 260. In this example, the inductances of the inductors 230 and 240 and the capacitances of the capacitors 250 and 260 may be selected (e.g., based on equations (3) and (4)) to provide the impedance inversion.

Thus, the exemplary topology shown in FIG. 2 is able to achieve impedance inversion and impedance matching at the same time using the inductors 230 and 240 of the second transformer 220 and the capacitors 250 and 260. The exemplary topology eliminates the need for the separate impedance inverter 155 shown in FIG. 1, which helps reduce area and make the voltage combiner 210 more compact. For instance, for the example where the impedance inverter 155 includes a transformer, the exemplary topology eliminates the need for the additional transformer to perform the impedance inversion.

In certain aspects, the second capacitor 260 may be implemented on a surface-mount device (SMD) or another off-die capacitor implementation that is separate from the die (e.g., gallium arsenide (GaAs) die) on which the auxiliary amplifier 120 is integrated. However, implementing the second capacitor 260 on a SMD may cause self-resonance issues due to parasitic inductance. To mitigate the limitations of SMD, the second capacitor 260 may be partially or fully implemented on the die (e.g., GaAS die).

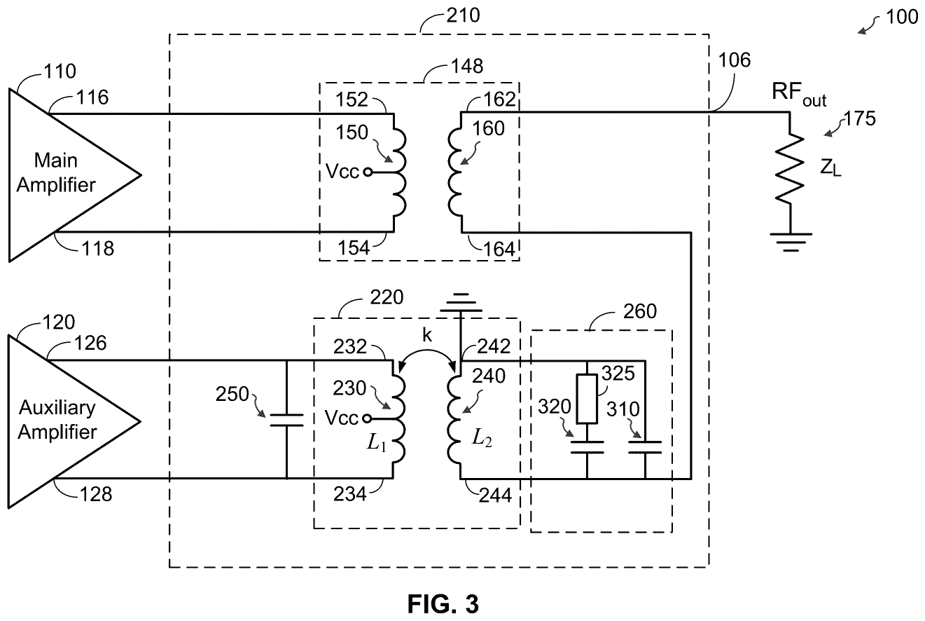

In this regard, FIG. 3 shows an example in which the second capacitor 260 is split into a capacitor 310 integrated on the die and a capacitor 320 that is off die (e.g., implemented on a SMD) with associated parasitic inductance 325, in which the capacitance of the second capacitor 260 is approximately equal to the combined capacitances of the capacitors 310 and 320. The parasitic inductance 325 may come from wiring coupling the capacitor 320 (e.g., implemented on the SMD) to the die. For the example where the capacitor 320 is implemented on the SMD, implementing the second capacitor 260 partially on the die mitigates the limitation of SMD self-resonance and reduces cost compared with fully implementing the second capacitor 260 on the SMD.

In certain aspects, a compact layout of the first transformer 148 and the second transformer 220 is achieved by nesting one of the transformers 148 and 220 within the other one of the transformers 148 and 220, as discussed further below. The compact layout significantly reduces the area occupied by the transformers 148 and 220 compared with laying out the transformers 148 and 220 side by side.

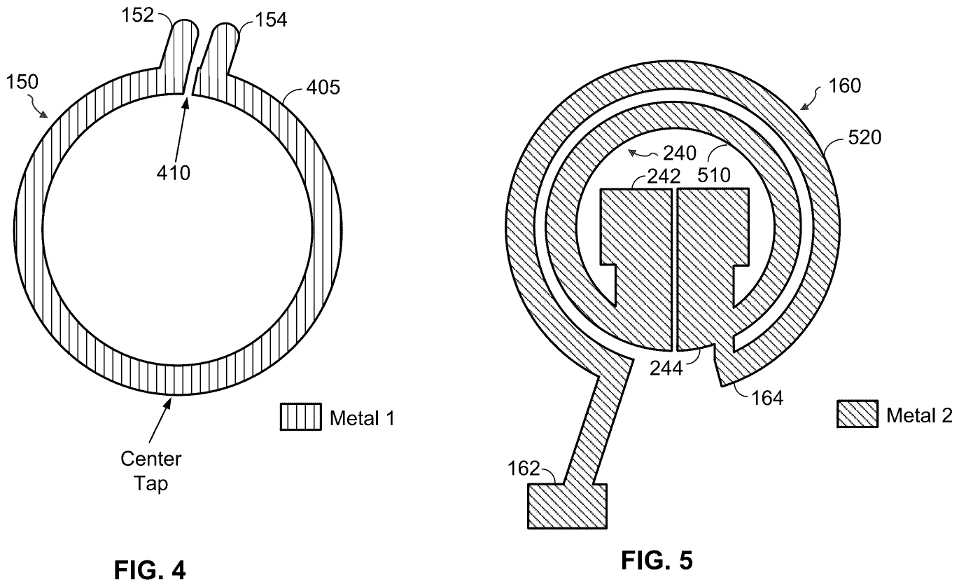

FIG. 4 shows a top view of an exemplary layout of the first inductor 150 according to certain aspects. In this example, the first inductor 150 is planar and formed in a first metal layer (e.g., using a lithographic and etching process). The first metal layer may be on and/or embedded in a substrate (e.g., a silicon substrate, a laminate, a ceramic, a PCB, etc.).

The first inductor 150 may include a loop 405 (shown in the example in FIG. 4), a spiral, or the like. In the example in FIG. 4, the loop 405 has a small gap 410 separating the first terminal 152 and the second terminal 154 of the first inductor 150. FIG. 4 also shows an exemplary location for the center tap of the first inductor 150, which may be DC biased with the supply voltage Vcc, as discussed above.

FIG. 5 shows a top view of an exemplary layout of the fourth inductor 240 and the second inductor 160 according to certain aspects. In this example, the fourth inductor 240 and the second inductor 160 are planar and formed in a second metal layer (e.g., using a lithographic and etching process). The second metal layer may be located above or below the first metal layer with a dielectric layer between the second metal layer and the first metal layer.

In this example, the fourth inductor 240 may include a loop 510 (shown in the example in FIG. 5), a spiral, or the like. Also, the second inductor 160 may include a loop 520 (shown in the example in FIG. 5), a spiral, or the like. In the example in FIG. 5, the fourth inductor 240 is located (i.e., nested) within the loop 520 of the second inductor 160, which provides for a compact layout for the inductors 240 and 160.

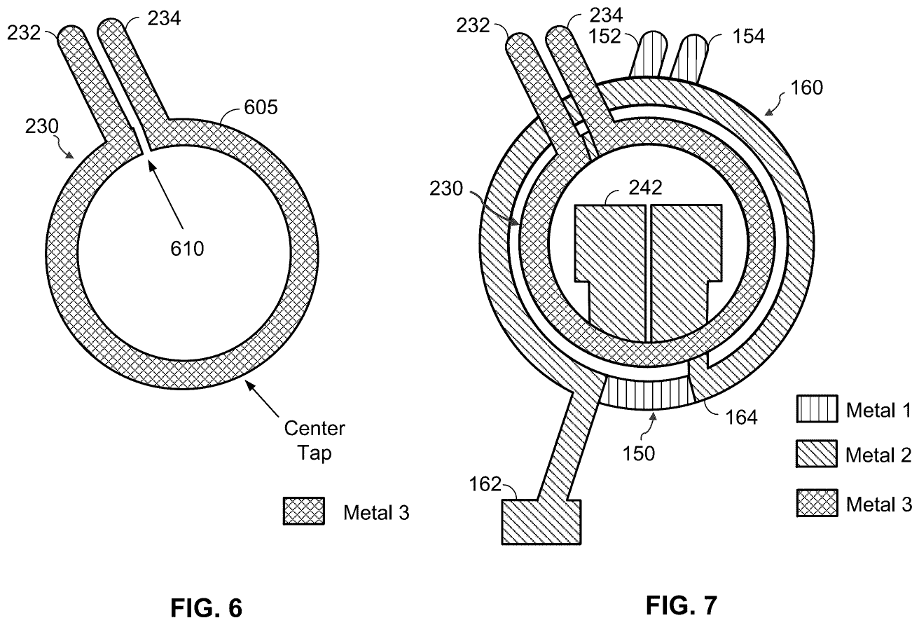

FIG. 6 shows a top view of an exemplary layout of the third inductor 230 according to certain aspects. In this example, the third inductor 230 is planar and formed in a third metal layer (e.g., using a lithographic and etching process). The third metal layer may be on and/or embedded in a substrate (e.g., a silicon substrate, a laminate, a ceramic, a PCB, etc.). The third metal layer may be located above or below the second metal layer with a dielectric layer between the second metal layer and the third metal layer.

The third inductor 230 may include a loop 605 (shown in the example in FIG. 6), a spiral, or the like. In the example in FIG. 6, the loop 605 has a small gap 610 separating the first terminal 232 and the second terminal 234 of the third inductor 230. FIG. 6 also shows an exemplary location for the center tap of the third inductor 230, which may be DC biased with the supply voltage Vcc, as discussed above.

FIG. 7 shows an example in which the inductors 150, 160, 230, and 240 of the transformers 220 and 148 are stacked according to certain aspects. In this example, the first metal layer is below the second metal layer and the third metal layer is above the second metal layer. However, it is to be appreciated that, in other implementations, the third metal layer may be below the second metal layer and the first metal layer may be above the second metal layer. In both cases, the second metal layer is between the first metal layer and the third metal layer.

In the example in FIG. 7, the second inductor 160 overlaps the first inductor 150 to facilitate magnetic coupling between the inductors 150 and 160. Note that most of the first inductor 150 is obscured in FIG. 7 since the first inductor 150 lies beneath the second inductor 160 in this example.

Also, in the example in FIG. 7, the third inductor 230 overlaps the fourth inductor 240 to facilitate magnetic coupling between the inductors 230 and 240. Note that most of the fourth inductor 240 is obscured in FIG. 7 since the fourth inductor 240 lies beneath the third inductor 230 in this example.

In this example, the stacking of the inductors 150, 160, 230, and 240 and the nesting of the fourth inductor 240 within the second inductor 160 in the second metal layer provide a compact layout that significantly reduces the area occupied by the transformers 148 and 220.

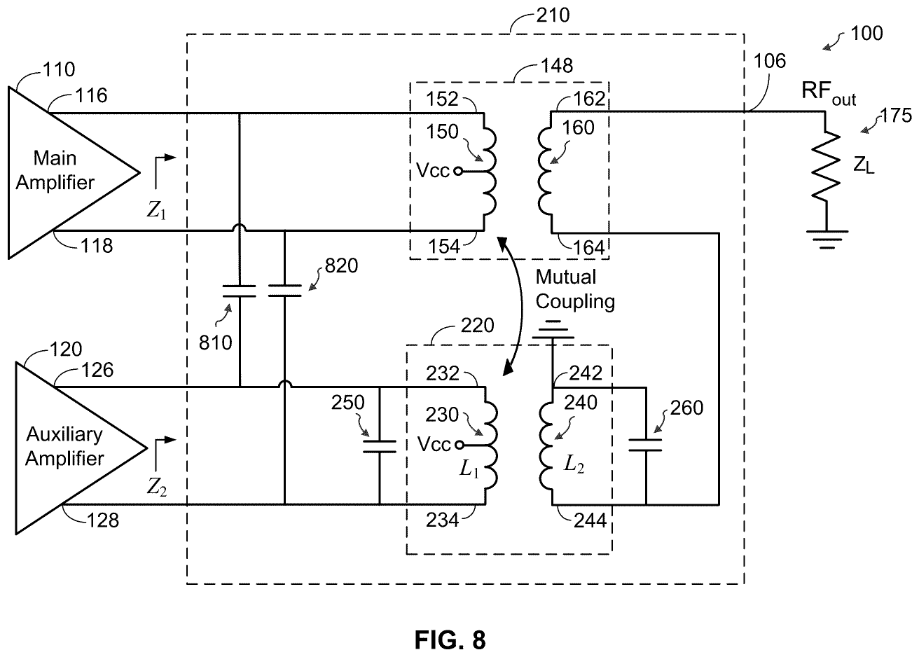

The compact layout may increase unwanted mutual coupling between the transformers 148 and 220. To address this, FIG. 8 shows an example in which the voltage combiner 210 includes a first cross capacitor 810 and a second cross capacitor 820 to cancel out at least a portion of the mutual coupling. The first cross capacitor 810 is coupled between the first output 116 of the main amplifier 110 and the first output 126 of the auxiliary amplifier 120, and the second cross capacitor 820 is coupled between the second output 118 of the main amplifier 110 and the second output 128 auxiliary amplifier 120. Each of the capacitors 810 and 820 may include a metal-oxide-metal (MOM) capacitor, a metal-insulator-metal (MIM) capacitor, a metal-oxide-semiconductor (MOS) capacitor, or any combination thereof.

In this example, since the mutual coupling between the transformers 148 and 220 is inductive, the mutual coupling may be canceled out by the capacitances of the cross capacitors 810 and 820. For example, in some implementations, the mutual coupling may be represented in z parameters by a single ended Z₁₂ value. In these implementations, the capacitances of the cross capacitors 810 and 820 may be selected to cancel out the single ended Z₁₂ value as follows:

$${C}_{c} = \frac{1}{2 π {f}_{c} 𝒥 ( {Z}_{12} )} \qquad ( 5 )$$

where C_{c} is the capacitance of each of the cross capacitors 810 and 820 and f_{c} is the center frequency of the output RF signals of the main amplifier 110 and the auxiliary amplifier 120.

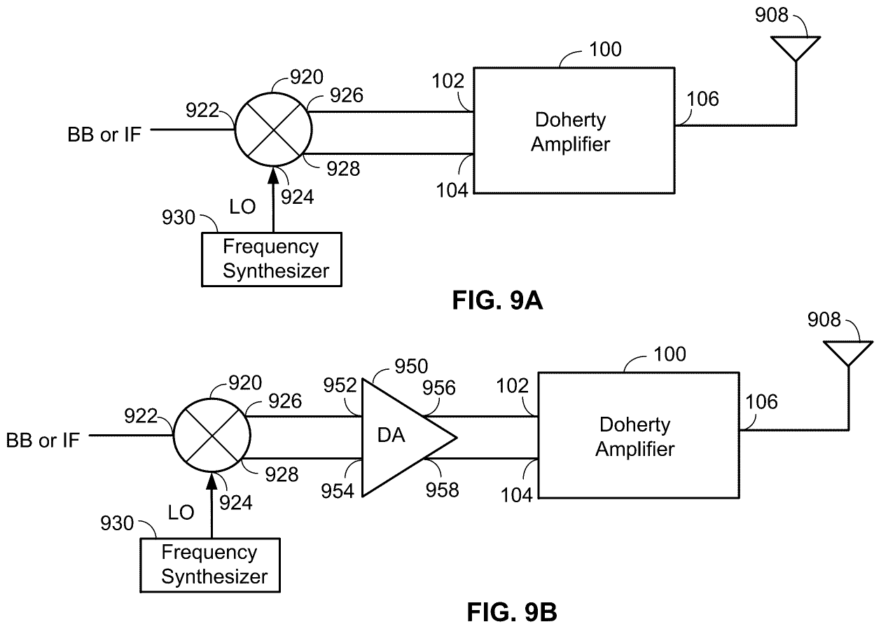

FIG. 9A shows an example of a mixer 920 coupled to the first input 102 and the second input 104 of the Doherty amplifier 100 to provide the differential input RF signal to the Doherty amplifier 100. In the example shown in FIG. 9A, the mixer 920 has a first input 922, a second input 924, and a differential output including a first output 926 and a second output 928. The mixer 920 is configured to receive a baseband signal (labeled “BB” in FIG. 9A) or an intermediate frequency (IF) signal at the first input 922 and a local oscillator signal (LO) at the second input 924. The LO signal is generated by a frequency synthesizer 930 (e.g., a phase-locked loop (PLL)) coupled to the second input 924 of the mixer 920. The mixer 920 and the Doherty amplifier 100 may be on separate chips or integrated on the same chip. In the example shown in FIG. 9A, the output of the Doherty amplifier 100 is coupled to an antenna 908.

For the example in which the first input 922 of the mixer 920 receives the baseband signal, the first input 922 may be coupled to a baseband processor, a baseband filter, and the like. For the example in which the first input 922 of the mixer 920 receives the IF signal, the input 922 may be coupled an IF circuit configured to frequency upconvert a baseband signal into the IF signal. The IF signal has a frequency between baseband and the frequency of the input RF signal.

During operation, the mixer 920 receives the baseband signal or the IF signal at the first input 922 (which may be single-ended or differential) and receives the LO signal from the frequency synthesizer 930 at the second input 924. The mixer 920 mixes the baseband signal or the IF signal with the LO signal to frequency upconvert the baseband signal or the IF signal into an RF signal. In the example in FIG. 9A, the mixer 920 outputs the RF signal as a differential RF signal at the first and second outputs 926 and 928 of the mixer 920, which may be coupled to the first and second inputs 102 and 104, respectively, of the Doherty amplifier 100.

It is to be appreciated that the transmitter may include one or more additional components not shown in FIG. 9A. For example, FIG. 9B shows an example in which the transmitter also includes a driver amplifier 950 (also referred to as a driver stage) coupled between the mixer 920 and the Doherty amplifier 100 for driving the inputs 102 and 104 of the Doherty amplifier 100 with the RF signal from the mixer 920. In the example in FIG. 9B, the driver amplifier 950 has a differential input including a first input 952 and a second input 954 and a differential output including a first output 956 and a second output 958. The first input 952 and the second input 954 may be coupled to the first output 926 and the second output 928, respectively, of the mixer 920, and the first output 956 and the second output 958 may be coupled to the first input 102 and the second input 104, respectively, of the Doherty amplifier 100. The driver amplifier 950 and the Doherty amplifier 100 may be on separate chips or integrated on the same chip. In some implementations, the transmitter may also include an inter-stage transformer (not shown) between the mixer 920 and the Doherty amplifier 100.

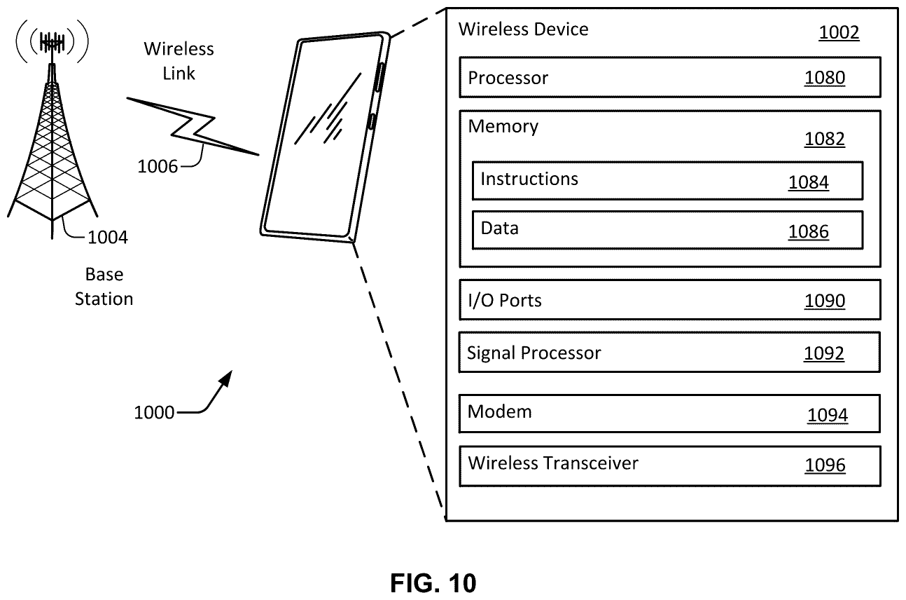

FIG. 10 is a diagram of an environment 1000 that includes a wireless device 1002 and a base station 1004. In the environment 1000, the wireless device 1002 communicates with the base station 1004 via a wireless link 1006. As shown, the wireless device 1002 is depicted as a smart phone. However, it is to be understood that the wireless device 1002 may be implemented as any suitable wireless device, such as a cellular base station, a broadband router, an access point, a cellular or mobile phone, a gaming device, a navigation device, a media device, a laptop computer, a desktop computer, a tablet computer, a server computer, a network-attached storage (NAS) device, a smart appliance, a vehicle-based communication system, an Internet of Things (IoT) device, a sensor or security device, an asset tracker, and so forth.

The base station 1004 communicates with the wireless device 1002 via the wireless link 1006, which may be implemented as any suitable type of wireless link. Although depicted as a base station tower of a cellular radio network, the base station 1004 may represent or be implemented as another device, such as a satellite, a terrestrial broadcast tower, an access point, a peer-to-peer device, a mesh network node, and so forth. The wireless link 1006 may include a downlink of data and/or control information communicated from the base station 1004 to the wireless device 1002 and an uplink of other data and/or control information communicated from the wireless device 1002 to the base station 1004. The wireless link 1006 may be implemented using any suitable communication protocol or standard, such as 3rd Generation Partnership Project Long-Term Evolution (3GPP LTE, 3GPP NR 5G), IEEE 1002.109, IEEE 1002.109, Bluetooth™, and so forth.

The wireless device 1002 includes a processor 1080 and a memory 1082. The memory 1082 may be or form a portion of a computer readable storage medium. The processor 1080 may include any type of processor, such as an application processor or a multi-core processor, that is configured to execute processor-executable instructions stored in the memory 1082. The memory 1082 may include any suitable type of data storage media, such as a volatile memory (e.g., random access memory (RAM)), a non-volatile memory (e.g., Flash memory), an optical media, a magnetic media (e.g., disk or tape), or any combination thereof. In the context of this disclosure, the memory 1082 may store instructions 1084, data 1086, and other information of the wireless device 1002.

The wireless device 1002 may also include input/output (I/O) ports 1090. The I/O ports 1090 enable data exchanges or interaction with other devices, networks, or users or between components of the wireless device 1002.

The wireless device 1002 may further include a signal processor (SP) 1092 (e.g., such as a digital signal processor (DSP)). The signal processor 1092 may function similar to the processor 1080 and may be capable of executing instructions and/or processing information in conjunction with the memory 1082.

For communication purposes, the wireless device 1002 also includes a modem 1094, a wireless transceiver 1096, and one or more antennas (e.g., the antenna 908). The wireless transceiver 1096 may include the Doherty amplifier 100, the mixer 920, and/or the driver amplifier 950 discussed above. The wireless transceiver 1096 provides connectivity to respective networks (e.g., the base station 1004) and other wireless devices connected therewith using RF signals. The wireless transceiver 1096 may facilitate communication over any suitable type of wireless network, such as a wireless local area network (LAN) (WLAN), a peer-to-peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

Implementation examples are described in the following numbered clauses:
1. A power amplifier, comprising:
   a main amplifier;
   an auxiliary amplifier;
   a first transformer, comprising:
      a first inductor coupled between a first output of the main amplifier and a second output of the main amplifier; and
      a second inductor magnetically coupled with the first inductor;
   a second transformer, comprising:
      a third inductor coupled between a first output of the auxiliary amplifier and a second output of the auxiliary amplifier; and
      a fourth inductor magnetically coupled with the third inductor, wherein the second inductor and the fourth inductor are coupled in series;
   a first capacitor coupled in parallel with the third inductor; and
   a second capacitor coupled in parallel with the fourth inductor, wherein the third inductor, the fourth inductor, the first capacitor, and the second capacitor are configured to provide impedance inversion.
2. The power amplifier of clause 1, wherein the second inductor and the fourth inductor are coupled to an antenna.
3. The power amplifier of clause 2, wherein the second inductor and the fourth inductor are coupled in series between the antenna and a ground.
4. The power amplifier of any one of clauses 1 to 3, wherein the second capacitor comprises an on-die capacitor and an off-die capacitor.
5. The power amplifier of clause 4, wherein the off-die capacitor comprises a surface-mount device (SMD) capacitor.
6. The power amplifier of any one of clauses 1 to 5, wherein a capacitance of the first capacitor is approximately equal to:

$$C = \frac{1}{{L}_{1} ( 1 - {k}^{2} ) {ω}^{2}}$$

where C is the capacitance of the first capacitor, L is an inductance of the third inductor, k is a coupling factor between the third inductor and the fourth inductor, and o is an angular frequency of an output radio frequency (RF) signal of the auxiliary amplifier.
7. The power amplifier of any one of clauses 1 to 6, further comprising:
   a first cross capacitor coupled between the first output of the main amplifier and the first output of the auxiliary amplifier; and
   a second cross capacitor coupled between the second output of the main amplifier and the second output of the auxiliary amplifier.
8. The power amplifier of any one of clauses 1 to 7, wherein the fourth inductor is nested within the second inductor.
9. The power amplifier of any one of clauses 1 to 8, wherein the second inductor comprises a loop and the fourth inductor is located within the loop of the second inductor.
10. The power amplifier of any one of clauses 1 to 9, wherein the first inductor is formed in a first metal layer, the second inductor and the fourth inductor are formed in a second metal layer, the third inductor is formed in a third metal layer, and the second metal layer is between the first metal layer and the third metal layer.
11. The power amplifier of clause 10, wherein the fourth inductor is nested within the second inductor.
12. The power amplifier of clause 10 or 11, wherein the second inductor comprises a loop and the fourth inductor is located within the loop of the second inductor.
13. The power amplifier of any one of clauses 10 to 12, wherein the first inductor overlaps the second inductor, and the third inductor overlaps the fourth inductor.
14. The power amplifier of any one of clauses 1 to 13, wherein the second inductor and the fourth inductor are adapted to be coupled in series between an antenna and a ground.
15. The power amplifier of any one of clauses 1 to 14, wherein a capacitance of the first capacitor is determined based on an inductance of the third inductor, a coupling factor between the third inductor and the fourth inductor, and an angular frequency of an output radio frequency (RF) signal of the auxiliary amplifier.
16. A system, comprising:
   a mixer;
   an input network, wherein an input of the input network is coupled to the mixer;
   a main amplifier, wherein an input of the main amplifier is coupled to a first output of the input network;
   an auxiliary amplifier, wherein an input of the auxiliary amplifier is coupled to a second output of the input network;
   a first transformer, comprising:
      a first inductor coupled between a first output of the main amplifier and a second output of the main amplifier; and
      a second inductor magnetically coupled with the first inductor;
   a second transformer, comprising:
      a third inductor coupled between a first output of the auxiliary amplifier and a second output of the auxiliary amplifier; and
      a fourth inductor magnetically coupled with the third inductor, wherein the second inductor and the fourth inductor are coupled in series;
   a first capacitor coupled in parallel with the third inductor; and
   a second capacitor coupled in parallel with the fourth inductor, wherein the third inductor, the fourth inductor, the first capacitor, and the second capacitor are configured to provide impedance inversion.
17. The system of clause 16, wherein the input network is configured to:
   receive an input radio frequency (RF) signal from the mixer;
   split the input RF signal into a first RF signal and a second RF signal;
   output the first RF signal at the first output of the input network; and
   output the second RF signal at the second output of the input network.
18. The system of clause 17, wherein the input network is further configured to provide a phase shift between the first RF signal and the second RF signal.
19. The system of clause 18, wherein the phase shift is approximately equal to 90 degrees.
20. The system of any one of clauses 16 to 19, further comprising a driver amplifier coupled between the mixer and the input of the input network.
21. The system of any one of clauses 16 to 20, further comprising an antenna coupled to the second inductor and the fourth inductor.
22. The system of clause 21, wherein the second inductor and the fourth inductor are coupled in series between the antenna and a ground.
23. The system of any one of clauses 16 to 22, wherein the second capacitor comprises an on-die capacitor and an off-die capacitor.
24. The system of clause 23, wherein the off-die capacitor comprises a surface-mount device (SMD) capacitor.
25. The system of any one of clauses 16 to 24, wherein a capacitance of the first capacitor is approximately equal to:

$$C = \frac{1}{{L}_{1} ( 1 - {k}^{2} ) {ω}^{2}}$$

where C is the capacitance of the first capacitor, L is an inductance of the third inductor, k is a coupling factor between the third inductor and the fourth inductor, and o is an angular frequency of an output radio frequency (RF) signal of the auxiliary amplifier.
26. The system of any one of clauses 16 to 25, further comprising:
   a first cross capacitor coupled between the first output of the main amplifier and the first output of the auxiliary amplifier; and
   a second cross capacitor coupled between the second output of the main amplifier and the second output of the auxiliary amplifier.
27. The system of any one of clauses 16 to 26, wherein the fourth inductor is nested within the second inductor.
28. The system of any one of clauses 16 to 27, wherein the second inductor comprises a loop and the fourth inductor is located within the loop of the second inductor.
29. The system of any one of clauses 16 to 28, wherein the first inductor is formed in a first metal layer, the second inductor and the fourth inductor are formed in a second metal layer, the third inductor is formed in a third metal layer, and the second metal layer is between the first metal layer and the third metal layer.
30. A power amplifier, comprising:
   a main amplifier;
   an auxiliary amplifier;
   a first transformer, comprising:
      a first inductor coupled between a first output of the main amplifier and a second output of the main amplifier; and
      a second inductor magnetically coupled with the first inductor;
   a second transformer, comprising:
      a third inductor coupled between a first output of the auxiliary amplifier and a second output of the auxiliary amplifier, wherein the first inductor and the third inductor are stacked;
      a fourth inductor magnetically coupled with the third inductor, wherein the second inductor and the fourth inductor are coupled in series;
   a first cross capacitor coupled between the first output of the main amplifier and the first output of the auxiliary amplifier; and
   a second cross capacitor coupled between the second output of the main amplifier and the second output of the auxiliary amplifier.
31. The power amplifier of clause 30, wherein the fourth inductor is nested within the second inductor.
32. The power amplifier of clause 30 or 31, wherein the second inductor comprises a loop and the fourth inductor is located within the loop of the second inductor.
33. The power amplifier of any one of clauses 30 to 32, wherein the first inductor is formed in a first metal layer, the second inductor and the fourth inductor are formed in a second metal layer, the third inductor is formed in a third metal layer, and the second metal layer is between the first metal layer and the third metal layer.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that the term “ground” may refer to a DC ground or an AC ground, and thus the term “ground” covers both possibilities. It is also to be appreciated that an “inductor” may include multiple inductors coupled in series. It is also to be appreciated than an “input” may be a single-ended input, a differential input, or one of two inputs of a differential input, and an “output” may be a single-ended output, a differential output, or one of two outputs of a differential output. The term “approximately” means within a range of between 90 percent and 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A power amplifier, comprising:
a main amplifier;
an auxiliary amplifier;
a first transformer, comprising:
a first inductor coupled between a first output of the main amplifier and a second output of the main amplifier; and
a second inductor magnetically coupled with the first inductor;
a second transformer, comprising:
a third inductor coupled between a first output of the auxiliary amplifier and a second output of the auxiliary amplifier; and
a fourth inductor magnetically coupled with the third inductor, wherein the second inductor and the fourth inductor are coupled in series;
a first capacitor coupled in parallel with the third inductor; and
a second capacitor coupled in parallel with the fourth inductor, wherein the third inductor, the fourth inductor, the first capacitor, and the second capacitor are configured to provide impedance inversion.

2. The power amplifier of claim 1, wherein the second inductor and the fourth inductor are coupled to an antenna.

3. The power amplifier of claim 2, wherein the second inductor and the fourth inductor are coupled in series between the antenna and a ground.

4. The power amplifier of claim 1, wherein the second capacitor comprises an on-die capacitor and an off-die capacitor.

5. The power amplifier of claim 4, wherein the off-die capacitor comprises a surface-mount device (SMD) capacitor.

6. The power amplifier of claim 1, wherein a capacitance of the first capacitor is approximately equal to:
$$C = \frac{1}{{L}_{1} ( 1 - {k}^{2} ) {ω}^{2}}$$
where C is the capacitance of the first capacitor, L is an inductance of the third inductor, k is a coupling factor between the third inductor and the fourth inductor, and CO is an angular frequency of an output radio frequency (RF) signal of the auxiliary amplifier.

7. The power amplifier of claim 1, further comprising:
a first cross capacitor coupled between the first output of the main amplifier and the first output of the auxiliary amplifier; and
a second cross capacitor coupled between the second output of the main amplifier and the second output of the auxiliary amplifier.

8. The power amplifier of claim 1, wherein the fourth inductor is nested within the second inductor.

9. The power amplifier of claim 1, wherein the second inductor comprises a loop and the fourth inductor is located within the loop of the second inductor.

10. The power amplifier of claim 1, wherein the first inductor is formed in a first metal layer, the second inductor and the fourth inductor are formed in a second metal layer, the third inductor is formed in a third metal layer, and the second metal layer is between the first metal layer and the third metal layer.

11. The power amplifier of claim 1, wherein the second inductor and the fourth inductor are adapted to be coupled in series between an antenna and a ground.

12. The power amplifier of claim 1, wherein a capacitance of the first capacitor is determined based on an inductance of the third inductor, a coupling factor between the third inductor and the fourth inductor, and an angular frequency of an output radio frequency (RF) signal of the auxiliary amplifier.

13. A system, comprising:
a mixer;
an input network, wherein an input of the input network is coupled to the mixer;
a main amplifier, wherein an input of the main amplifier is coupled to a first output of the input network;
an auxiliary amplifier, wherein an input of the auxiliary amplifier is coupled to a second output of the input network;
a first transformer, comprising:
a first inductor coupled between a first output of the main amplifier and a second output of the main amplifier; and
a second inductor magnetically coupled with the first inductor;
a second transformer, comprising:
a third inductor coupled between a first output of the auxiliary amplifier and a second output of the auxiliary amplifier; and
a fourth inductor magnetically coupled with the third inductor, wherein the second inductor and the fourth inductor are coupled in series;
a first capacitor coupled in parallel with the third inductor; and
a second capacitor coupled in parallel with the fourth inductor, wherein the third inductor, the fourth inductor, the first capacitor, and the second capacitor are configured to provide impedance inversion.

14. The system of claim 13, wherein the input network is configured to:
receive an input radio frequency (RF) signal from the mixer;
split the input RF signal into a first RF signal and a second RF signal;
output the first RF signal at the first output of the input network; and
output the second RF signal at the second output of the input network.

15. The system of claim 14, wherein the input network is further configured to provide a phase shift between the first RF signal and the second RF signal.

16. The system of claim 13, further comprising an antenna coupled to the second inductor and the fourth inductor.

17. The system of claim 16, wherein the second inductor and the fourth inductor are coupled in series between the antenna and a ground.

18. The system of claim 13, wherein the second capacitor comprises an on-die capacitor and an off-die capacitor.

19. The system of claim 13, wherein a capacitance of the first capacitor is approximately equal to:
$$C = \frac{1}{{L}_{1} ( 1 - {k}^{2} ) {ω}^{2}}$$
where C is the capacitance of the first capacitor, L is an inductance of the third inductor, k is a coupling factor between the third inductor and the fourth inductor, and CO is an angular frequency of an output radio frequency (RF) signal of the auxiliary amplifier.

20. The system of claim 13, further comprising:
a first cross capacitor coupled between the first output of the main amplifier and the first output of the auxiliary amplifier; and
a second cross capacitor coupled between the second output of the main amplifier and the second output of the auxiliary amplifier.

21. The system of claim 13, wherein the first inductor is formed in a first metal layer, the second inductor and the fourth inductor are formed in a second metal layer, the third inductor is formed in a third metal layer, and the second metal layer is between the first metal layer and the third metal layer.

22. A power amplifier, comprising:
a main amplifier;
an auxiliary amplifier;
a first transformer, comprising:
a first inductor coupled between a first output of the main amplifier and a second output of the main amplifier; and
a second inductor magnetically coupled with the first inductor;
a second transformer, comprising:
a third inductor coupled between a first output of the auxiliary amplifier and a second output of the auxiliary amplifier, wherein the first inductor and the third inductor are stacked;
a fourth inductor magnetically coupled with the third inductor, wherein the second inductor and the fourth inductor are coupled in series;
a first cross capacitor coupled between the first output of the main amplifier and the first output of the auxiliary amplifier; and
a second cross capacitor coupled between the second output of the main amplifier and the second output of the auxiliary amplifier.

23. The power amplifier of claim 22, wherein the fourth inductor is nested within the second inductor.

24. The power amplifier of claim 22, wherein the second inductor comprises a loop and the fourth inductor is located within the loop of the second inductor.

25. The power amplifier of claim 22, wherein the first inductor is formed in a first metal layer, the second inductor and the fourth inductor are formed in a second metal layer, the third inductor is formed in a third metal layer, and the second metal layer is between the first metal layer and the third metal layer.
